(19) United States
(12) Patent Application Publication
(10) Pub. No.: US 2026/0047261 A1
(43) Pub. Date: Feb. 12, 2026

(54) DISPLAY DEVICE AND ELECTRONIC DEVICE INCLUDING THE SAME

(71) Applicant: Samsung Display Co., LTD., Yongin-si (KR)

(72) Inventor: Hyo Jin KO, Yongin-si (KR)

(73) Assignee: Samsung Display Co., LTD., Yongin-si (KR)

(21) Appl. No.: 19/261,169

(22) Filed: Jul. 7, 2025

(30) Foreign Application Priority Data
Aug. 12, 2024 (KR) 10-2024-0107697

(51) Int. Cl. H10H 29/856; H01L 25/075

(52) U.S. Cl. CPC H10H 29/856; H01L 25/0753

(57) ABSTRACT

A display device includes a common electrode, a light emitting element between a pixel electrode and the common electrode, a reflective layer covering a side surface of the light emitting element, an element insulating layer disposed between the reflective layer and the light emitting element, a first passivation layer disposed between a pixel circuit layer and the common electrode, a second passivation layer disposed on the common electrode, and a reflective wall defining a closed curve shape of a reflective opening surrounding the light emitting element in a plan view, and the reflective wall fills a groove passing through the second passivation layer and the common electrode in a direction facing the pixel circuit layer.

### CROSS-REFERENCE TO RELATED APPLICATION(S)

This application claims priority to and benefits of Korean Patent Application No. 10-2024-0107697 under 35 U.S. C. § 119, filed on Aug. 12, 2024, the entire contents of which are incorporated herein by reference.

### BACKGROUND

### 1. Technical Field

The disclosure relates to a display device and an electronic device including the display device.

### 2. Description of the Related Art

Recently, as interest in an information display is being increased, research and development on a display device is being continuously conducted.

It is to be understood that this background of the technology section is, in part, intended to provide useful background for understanding the technology. However, this background of the technology section may also include ideas, concepts, or recognitions that were not part of what was known or appreciated by those skilled in the pertinent art prior to a corresponding effective filing date of the subject matter disclosed herein.

### SUMMARY

An object of the disclosure is to provide a display device capable of preventing light mixing between adjacent sub-pixels.

According to embodiments of the disclosure, a display device may include a pixel electrode disposed on a pixel circuit layer; a common electrode facing the pixel electrode; a light emitting element disposed between the pixel electrode and the common electrode, and including a first semiconductor layer connected to the pixel electrode, a second semiconductor layer connected to the common electrode; and an active layer disposed between the first semiconductor layer and the second semiconductor layer; a reflective layer covering a side surface of the light emitting element; an element insulating layer disposed between the reflective layer and the light emitting element; a first passivation layer disposed between the pixel circuit layer and the common electrode, a second passivation layer disposed on the common electrode; and a reflective wall defining a closed curve shape of a reflective opening surrounding the light emitting element in a plan view, and the reflective wall fills a groove passing through the second passivation layer and the common electrode in a direction facing the pixel circuit layer.

In an embodiment, the reflective wall may directly contact the common electrode.

In an embodiment, the groove may further pass through the first passivation layer adjacent to the common electrode.

In an embodiment, the groove may expose an upper surface of the pixel circuit layer.

In an embodiment, the display device may further include a light extraction part disposed on the second passivation layer, surrounded by the reflective opening in a plan view, and convex in a direction opposite to the direction facing the pixel circuit layer.

In an embodiment, the reflective wall may be spaced apart from the pixel electrode.

In an embodiment, the reflective layer may cover a side surface of the pixel electrode, and the element insulating layer may be disposed between the pixel electrode and the reflective layer.

In an embodiment, the display device may further include an auxiliary electrode disposed between the pixel electrode and the first semiconductor layer.

In an embodiment, the reflective wall may be spaced apart from the auxiliary electrode.

In an embodiment, the reflective wall may include a material of which a light transmittance is about 5% or less, a light reflectance is about 60% or more, and a resistance is about 10Ω or less.

In an embodiment, the reflective wall may include copper.

In an embodiment, the light emitting element may have a reverse taper shape in which a width gradually increases along a direction away from the pixel circuit layer, in a cross-sectional view.

According to embodiments, a display device may include a pixel electrode disposed on a pixel circuit layer; a common electrode facing the pixel electrode; a light emitting element disposed between the pixel electrode and the common electrode, and including a first semiconductor layer connected to the pixel electrode; a second semiconductor layer connected to the common electrode; and an active layer disposed between the first semiconductor layer and the second semiconductor layer; a first passivation layer disposed between the pixel circuit layer and the common electrode, a second passivation layer disposed on the common electrode; and a reflective wall defining a closed curve shape of a reflective opening surrounding the light emitting element in a plan view, and the reflective wall may fill a groove passing through the second passivation layer, the common electrode, and the first passivation layer in a direction facing the pixel circuit layer.

In an embodiment, the first passivation layer may directly contact a side surface of the light emitting element.

In an embodiment, the groove may expose an upper surface of the pixel circuit layer.

In an embodiment, the reflective wall may directly contact the common electrode.

In an embodiment, the display device may further include a light extraction part disposed on the second passivation layer, surrounded by the reflective opening in a plan view, and convex in a direction opposite to the direction facing the pixel circuit layer.

In an embodiment, the reflective wall may be spaced apart from the pixel electrode.

In an embodiment, the display device may further include an auxiliary electrode disposed between the pixel electrode and the first semiconductor layer.

In an embodiment, the reflective wall may be spaced apart from the auxiliary electrode.

According to embodiments of the disclosure, an electronic device may include a processor that provides input image data, and a display device that displays an image based on the input image data. The display device may include a pixel electrode disposed on a pixel circuit layer; a common electrode facing the pixel electrode; a light emitting element disposed between the pixel electrode and the common electrode, and including a first semiconductor layer connected to the pixel electrode, a second semiconductor layer connected to the common electrode; and an active layer disposed between the first semiconductor layer and the second semiconductor layer; a reflective layer covering a side surface of the light emitting element; an element insulating layer disposed between the reflective layer and the light emitting element; a first passivation layer disposed between the pixel circuit layer and the common electrode; a second passivation layer disposed on the common electrode; and a reflective wall defining a closed curve shape of reflective opening surrounding the light emitting element in a plan view, and the reflective wall fills a groove passing through the second passivation layer and the common electrode in a direction facing the pixel circuit layer.

The reflective wall may directly contacts the common electrode.

The groove may further pass through the first passivation layer adjacent to the common electrode.

The groove may expose an upper surface of the pixel circuit layer.

The electronic device may further comprise a light extraction part disposed on the second passivation layer, surrounded by the reflective opening in a plan view, and convex in a direction opposite to the direction facing the pixel circuit layer.

The reflective wall may be spaced apart from the pixel electrode.

The electronic device may be at least one of an organic light-emitting display apparatus, an inorganic light-emitting display apparatus, a quantum dot light-emitting display apparatus, display screens of portable electronic apparatus, such as mobile phones, smartphones, tablet personal computers (PCs), mobile communication terminals, electronic notebooks, electronic books, portable multimedia players (PMPs), navigation devices, and ultra mobile PCs (UMPCs), display screens of televisions, notebooks, monitors, advertisement panels, Internet of things (IoT) devices, a portable communication device a smartphone, a computer device, a portable multimedia device, a portable medical device, a camera, a wearable device, and a home appliance.

A display device according to embodiments may include a reflective wall. The reflective wall may define a closed curve shape of a reflective opening surrounding a light emitting element in a plan view and may fill a groove passing through a second passivation layer and a common electrode.

Light totally reflected at interfaces between the common electrode and layers contacting the common electrode may be reflected by the reflective wall. Light totally reflected at an interface between the second passivation layer and a layer contacting the second passivation layer may be reflected by the reflective wall. Therefore, light mixing of light emitted from the light emitting element may be prevented.

### BRIEF DESCRIPTION OF THE DRAWINGS

The above and other features of the disclosure will become more apparent by describing in further detail embodiments thereof with reference to the accompanying drawings, in which:

FIG. 1 is a block diagram illustrating a display device according to embodiments of the disclosure;

FIG. 2 is a block diagram illustrating one sub-pixel among sub-pixels included in the display device of FIG. 1;

FIG. 3 is a schematic plan view illustrating a display panel configuring the display device of FIG. 1;

FIG. 4 is a schematic plan view illustrating a pixel according to an embodiment of the disclosure;

FIG. 5 is a schematic cross-sectional view illustrating a first embodiment of the pixel of FIG. 4;

FIG. 6 is a schematic cross-sectional view illustrating a second embodiment of the pixel of FIG. 4;

FIG. 7 is a schematic cross-sectional view illustrating a third embodiment of the pixel of FIG. 4;

FIG. 8 is a schematic cross-sectional view illustrating a fourth embodiment of the pixel of FIG. 4;

FIG. 9 is a schematic cross-sectional view illustrating a fifth embodiment of the pixel of FIG. 4;

FIG. 10 is a schematic cross-sectional view illustrating a sixth embodiment of the pixel of FIG. 4;

FIGS. 11 to 15 are schematic plan views illustrating a reflective partition wall (or reflective wall) according to embodiments of the disclosure;

FIG. 16 is a block diagram illustrating a display system according to an embodiment; and

FIGS. 17 and 18 are schematic perspective views illustrating application examples of the display system of FIG. 16.

### DETAILED DESCRIPTION OF THE EMBODIMENTS

Hereinafter, embodiments according to the disclosure are described in detail with reference to the accompanying drawings. It should be noted that in the following description, portions desirable for understanding an operation according to the disclosure are described, and descriptions of other portions may be omitted in order not to obscure the subject matter of the disclosure. The disclosure may be embodied in other forms without being limited to the embodiments described herein. However, the embodiments described herein are provided to describe in detail enough to readily implement the technical spirit of the disclosure to those skilled in the art to which the disclosure belongs. As used herein, the singular forms, “a,” “an,” and “the” are intended to include the plural forms as well, unless the context clearly indicates otherwise.

In the specification and the claims, the term “and/or” is intended to include any combination of the terms “and” and “or” for the purpose of its meaning and interpretation. For example, “A and/or B” may be understood to mean “A, B, or A and B.” The terms “and” and “or” may be used in the conjunctive or disjunctive sense and may be understood to be equivalent to “and/or.”

In the specification and the claims, the phrase “at least one of” is intended to include the meaning of “at least one selected from the group of” for the purpose of its meaning and interpretation. For example, “at least one of A and B” may be understood to mean “A, B, or A and B.”

Throughout the specification, in a case where a portion is “connected” to another portion, the case includes not only a case where the portion is “directly connected” but also a case where the portion is “indirectly connected” with another element disposed therebetween. Terms used herein are for describing embodiments and are not intended to limit the disclosure. Throughout the specification, in a case where a certain portion “includes”, the case means that the portion may further include another component without excluding another component unless otherwise stated.

Here, terms such as first and second may be used to describe various components, but these components are not limited to these terms. These terms are used to distinguish one component from another component. Therefore, a first component may refer to a second component without departing from the scope disclosed herein.

Spatially relative terms such as “under”, “on”, and the like may be used for descriptive purposes, thereby describing a relationship between one element or feature and another element(s) or feature(s) as shown in the drawings. Spatially relative terms are intended to include other directions in use, in operation, and/or in manufacturing, in addition to the direction depicted in the drawings. For example, when a device shown in the drawing is turned upside down, elements depicted as being positioned “under” other elements or features are positioned in a direction “on” the other elements or features. Therefore, in an embodiment, the term “under” may include both directions of on and under. The device may face in other directions (for example, rotated 90 degrees or in other directions) and thus the spatially relative terms used herein are interpreted according thereto.

The terms “overlap” or “overlapped” mean that a first object may be above or below or to a side of a second object, and vice versa. Additionally, the term “overlap” may include layer, stack, face or facing, extending over, covering, or partly covering or any other suitable term as would be appreciated and understood by those of ordinary skill in the art.

The terms “face” and “facing” mean that a first element may directly or indirectly oppose a second element. In a case in which a third element intervenes between the first and second element, the first and second element may be understood as being indirectly opposed to one another, although still facing each other.

When an element is described as ‘not overlapping’ or ‘to not overlap’ another element, this may include that the elements are spaced apart from each other, offset from each other, or set aside from each other or any other suitable term as would be appreciated and understood by those of ordinary skill in the art.

The terms “comprises,” “comprising,” “includes,” and/or “including,” “has,” “have,” and/or “having,” and variations thereof when used in this specification, specify the presence of stated features, integers, steps, operations, elements, components, and/or groups thereof, but do not preclude the presence or addition of one or more other features, integers, steps, operations, elements, components, and/or groups thereof.

Various embodiments are described with reference to drawings schematically illustrating various embodiments. Accordingly, it will be expected that shapes may vary, for example, according to tolerances and/or manufacturing techniques. Therefore, the embodiments disclosed herein cannot be construed as being limited to shown specific shapes, and should be interpreted as including, for example, changes in shapes that occur as a result of manufacturing. As described above, the shapes shown in the drawings may not show actual shapes of areas of a device, and the embodiments are not limited thereto.

“About” or “approximately” as used herein is inclusive of the stated value and means within an acceptable range of deviation for the particular value as determined by one of ordinary skill in the art, considering the measurement in question and the error associated with measurement of the particular quantity (i.e., the limitations of the measurement system). For example, “about” may mean within one or more standard deviations, or within ±30%, 20%, 10%, 5% of the stated value.

Unless otherwise defined or implied herein, all terms (including technical and scientific terms) used herein have the same meaning as commonly understood by one of ordinary skill in the art to which the disclosure pertains. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

Embodiments may be described and illustrated in the accompanying drawings in terms of functional blocks, units, and/or modules.

Those skilled in the art will appreciate that these blocks, units, and/or modules are physically implemented by electronic (or optical) circuits, such as logic circuits, discrete components, microprocessors, hard-wired circuits, memory elements, wiring connections, and the like, which may be formed using semiconductor-based fabrication techniques or other manufacturing technologies.

In the case of the blocks, units, and/or modules being implemented by microprocessors or other similar hardware, they may be programmed and controlled using software (for example, microcode) to perform various functions discussed herein and may optionally be driven by firmware and/or software.

It is also contemplated that each block, unit, and/or module may be implemented by dedicated hardware, or as a combination of dedicated hardware to perform some functions and a processor (for example, one or more programmed microprocessors and associated circuitry) to perform other functions.

Each block, unit, and/or module of embodiments may be physically separated into two or more interacting and discrete blocks, units, and/or modules without departing from the scope of the disclosure.

Further, the blocks, units, and/or modules of embodiments may be physically combined into more complex blocks, units, and/or modules without departing from the scope of the disclosure.

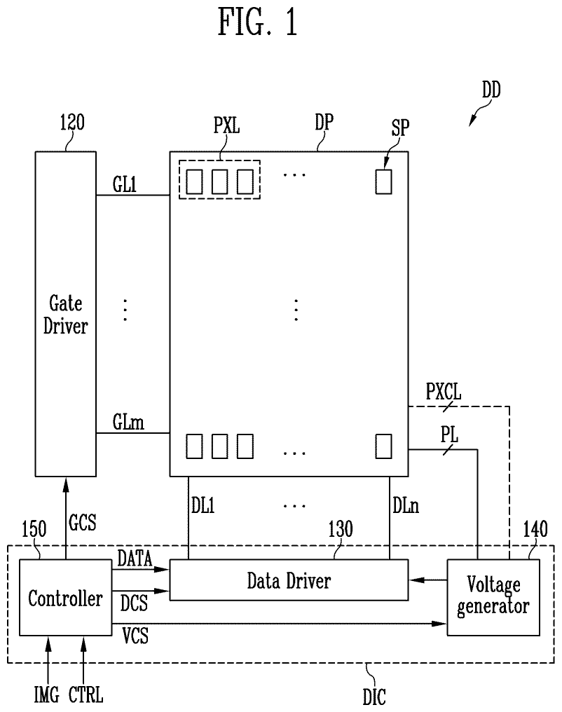

FIG. 1 is a block diagram illustrating a display device according to embodiments of the disclosure.

Referring to FIG. 1, the display device DD may include a display panel DP, a gate driver 120, a data driver 130, a voltage generator 140, and a controller 150.

The display panel DP may include sub-pixels SP. The sub-pixels SP may be connected to the gate driver 120 through first to m-th gate lines GL1 to GLm. The sub-pixels SP may be connected to the data driver 130 through first to n-th data lines DL1 to DLn.

The sub-pixels SP may generate light of two or more colors. For example, each of the sub-pixels SP may generate light such as red, green, blue, cyan, magenta, or yellow.

Two or more sub-pixels among the sub-pixels SP may configure one pixel PXL. For example, the pixel PXL may include three sub-pixels as shown in FIG. 1. As described above, the pixel PXL may emit light of various colors and various luminances according to a combination of light emitted from the sub-pixels included in the pixel PXL.

The gate driver 120 may be connected to the sub-pixels SP arranged (or disposed) in a row direction through the first to m-th gate lines GL1 to GLm. The gate driver 120 may output gate signals to the first to m-th gate lines GL1 to GLm in response to a gate control signal GCS. In embodiments, the gate control signal GCS may include a start signal indicating a start of each frame, a horizontal synchronization signal, and the like within the spirit and the scope of the disclosure.

The gate driver 120 may be disposed on one side or a side of the display panel DP. However, embodiments are not limited thereto. For example, the gate driver 120 may be divided into two or more physically and/or logically divided drivers, and such drivers may be disposed on one side or a side of the display panel DP and another side of the display panel DP opposite the one side or a side. As described above, the gate driver 120 may be disposed around the display panel DP in various shapes according to embodiments.

The data driver 130 may be connected to the sub-pixels SP arranged in a column direction through the first to n-th data lines DL1 to DLn. The data driver 130 may receive image data DATA and a data control signal DCS from the controller 150. The data driver 130 may operate in response to the data control signal DCS. In embodiments, the data control signal DCS may include a source start signal, a source shift clock, a source output enable signal, and the like within the spirit and the scope of the disclosure.

The data driver 130 may receive voltages from the voltage generator 140. The data driver 130 may apply data signals having grayscale voltages corresponding to the image data DATA to the first to n-th data lines DL1 to DLn using the received voltages. In case that the gate signal is applied to each of the first to m-th gate lines GL1 to GLm, the data signals corresponding to the image data DATA may be applied to the data lines DL1 to DLn. Accordingly, the sub-pixels SP may generate light corresponding to the data signals, and the display panel DP may display an image.

In embodiments, the gate driver 120 and the data driver 130 may include complementary metal-oxide semiconductor (CMOS) circuit elements.

The voltage generator 140 may operate in response to a voltage control signal VCS from the controller 150. The voltage generator 140 may be configured to generate voltages and provide the generated voltages to components of the display device DD, such as the gate driver 120, the data driver 130, and the controller 150. The voltage generator 140 may generate the voltages by receiving an input voltage from an outside of the display device DD and regulating the received voltage.

The voltage generator 140 may generate a first power voltage and a second power voltage. The generated first and second power voltages may be provided to the sub-pixels SP through power lines PL. In other embodiments, at least one of the first and second power voltages may be provided from the outside of the display device DD.

The voltage generator 140 may provide various voltages and/or signals. For example, the voltage generator 140 may provide one or more initialization voltages applied to the sub-pixels SP. For example, during a sensing operation for sensing electrical characteristics of transistors and/or light emitting elements of the sub-pixels SP, a selectable reference voltage may be applied to the first to n-th data lines DL1 to DLn, and the voltage generator 140 may generate the reference voltage and transmit the reference voltage to the data driver 130. For example, during a display operation for displaying an image on the display panel DP, common pixel control signals may be applied to the sub-pixels SP, and the voltage generator 140 may generate the pixel control signals. In embodiments, the voltage generator 140 may provide the pixel control signals to the sub-pixels SP through pixel control lines PXCL. In FIG. 1, the pixel control lines PXCL are connected between the voltage generator 140 and the display panel DP, but embodiments are not limited thereto. For example, the pixel control lines PXCL may be connected between the gate driver 120 and the display panel DP. In this case, the pixel control signals may be transmitted from the voltage generator 140 to the pixel control lines PXCL through the gate driver 120.

The controller 150 may control overall operations of the display device DD. The controller 150 may receive input image data IMG and a control signal CTRL corresponding thereto from the outside. The controller 150 may provide the gate control signal GCS, the data control signal DCS, and the voltage control signal VCS in response to the control signal CTRL.

The controller 150 may convert the input image data IMG so that the input image data IMG is suitable for the display device DD or the display panel DP and output the image data DATA. In embodiments, the controller 150 may output the image data DATA by aligning the input image data IMG so that the input image data IMG is suitable for the sub-pixels SP of a row unit.

Two or more components of the data driver 130, the voltage generator 140, and the controller 150 may be mounted on one integrated circuit. As shown in FIG. 1, the data driver 130, the voltage generator 140, and the controller 150 may be included in a driver integrated circuit DIC. In this case, the data driver 130, the voltage generator 140, and the controller 150 may be functionally divided components in one driver integrated circuit DIC. In other embodiments, at least one of the data driver 130, the voltage generator 140, and the controller 150 may be provided as a component distinguished from the driver integrated circuit DIC.

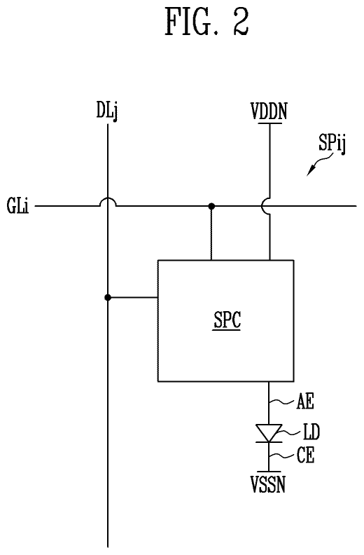

FIG. 2 is a block diagram illustrating one sub-pixel among the sub-pixels included in the display device of FIG. 1. In FIG. 2, among the sub-pixels SP of FIG. 1, a sub-pixel SPij arranged in an i-th row (i is an integer greater than or equal to 1 and less than or equal to m) and a j-th column (j is an integer greater than or equal to 1 and less than or equal to n) is shown as an example.

Referring to FIG. 2, the sub-pixel SPij may include a sub-pixel circuit SPC and a light emitting element LD.

The light emitting element LD may be connected between a first power voltage node VDDN and a second power voltage node VSSN. The first power voltage node VDDN may be connected to one of the power lines PL of FIG. 1 and receives the first power voltage. The second power voltage node VSSN may be connected to another one of the power lines PL of FIG. 1 and may receive the second power voltage. The first power voltage may have a voltage level higher than that of the second power voltage.

The light emitting element LD may be connected between a pixel electrode AE and a common electrode CE. The pixel electrode AE may be connected to the first power voltage node VDDN through the sub-pixel circuit SPC. For example, the pixel electrode AE may be connected to the first power voltage node VDDN through one or more transistors included in the sub-pixel circuit SPC. The common electrode CE may be connected to the second power voltage node VSSN. The light emitting element LD may be configured to emit light according to a current flowing from the pixel electrode AE to the common electrode CE.

In an embodiment, the pixel electrode AE may be referred to as one of an anode electrode and a cathode electrode, and the common electrode CE may be referred to as the other of the anode electrode and the cathode electrode. For example, the pixel electrode AE may be referred to as the anode electrode, and the common electrode CE may be referred to as the cathode electrode.

The sub-pixel circuit SPC may be connected to an i-th gate line GLi among the first to m-th gate lines GL1 to GLm of FIG. 1, and a j-th data line DLj among the first to n-th data lines DL1 to DLn of FIG. 1. In response to a gate signal received through the i-th gate line GLi, the sub-pixel circuit SPC may control the light emitting element LD to emit light according to a data signal received through the j-th data line DLj. In embodiments, the sub-pixel circuit SPC may be further connected to the pixel control lines PXCL of FIG. 1. In this case, the sub-pixel circuit SPC may control the light emitting element LD in further response to the pixel control signals received through the pixel control lines PXCL.

For such operations, the sub-pixel circuit SPC may include circuit elements, for example, transistors and one or more capacitors.

The transistors of the sub-pixel circuit SPC may include P-type transistors and/or N-type transistors. In embodiments, the transistors of the sub-pixel circuit SPC may include a metal oxide silicon field effect transistor (MOSFET). In embodiments, the transistors of the sub-pixel circuit SPC may include an amorphous silicon semiconductor, a monocrystalline silicon semiconductor, a polycrystalline silicon semiconductor, an oxide semiconductor, and the like within the spirit and the scope of the disclosure.

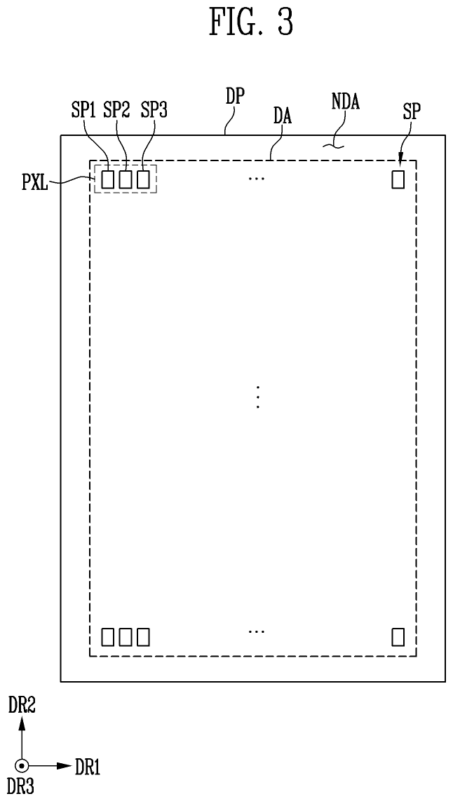

FIG. 3 is a schematic plan view illustrating the display panel configuring the display device of FIG. 1.

Referring to FIG. 3, the display panel DP may include a display area DA and a non-display area NDA. The display panel DP may display an image through the display area DA. The non-display area NDA may be disposed around the display area DA.

The display panel DP may include the sub-pixels SP in the display area DA. The sub-pixels SP may be arranged along a first direction DR1 and a second direction DR2 intersecting the first direction DR1. For example, the sub-pixels SP may be arranged in a matrix form along the first direction DR1 and the second direction DR2. As another example, the sub-pixels SP may be arranged in a zigzag form along the first direction DR1 and the second direction DR2. An arrangement of the sub-pixels SP may vary according to embodiments. The first direction DR1 may be a column direction, and the second direction DR2 may be a row direction.

Two or more sub-pixels among the sub-pixels SP may configure one pixel PXL. In FIG. 3, the pixel PXL may include three sub-pixels SP1, SP2, and SP3, but embodiments are not limited thereto. For example, the pixel PXL may include two sub-pixels. Hereinafter, for convenience of description, it is assumed that the pixel PXL may include the first to third sub-pixels SP1, SP2, and SP3.

Each of the first to third sub-pixels SP1, SP2, and SP3 may generate light of one of various colors, such as red, green, blue, cyan, magenta, and yellow. Hereinafter, for clarity and concise description, it is assumed that the first sub-pixel SP1 is configured to generate red color light, the second sub-pixel SP2 is configured to generate green color light, and the third sub-pixel SP3 is configured to generate blue color light.

Each of the first to third sub-pixels SP1, SP2, and SP3 may include at least one light emitting element configured to generate light. In embodiments, the light emitting elements of the first to third sub-pixels SP1, SP2, and SP3 may generate light of different colors. For example, the light emitting elements of the first to third sub-pixels SP1, SP2, and SP3 may generate the red color light, the green color light, and the blue color light, respectively. In other embodiments, the light emitting elements of the first to third sub-pixels SP1, SP2, and SP3 may generate light of the same color. For example, the light emitting elements of the first to third sub-pixels SP1, SP2, and SP3 may generate the blue color light.

As the display panel DP, a light emitting diode (LED) display panel using a micro-scale or nano-scale of light emitting diode as the light emitting element may be used.

Components for controlling the sub-pixels SP may be disposed in the non-display area NDA. Lines connected to the sub-pixels SP, for example, the first to m-th gate lines GL1 to GLm of FIG. 1, the first to n-th data lines DL1 to DLn, the power lines PL, and the pixel control lines PXCL may be disposed in the non-display area NDA.

At least one of the gate driver 120, the data driver 130, the voltage generator 140, and the controller 150 of FIG. 1 may be disposed in the non-display area NDA of the display panel DP. In this case, the data driver 130, the voltage generator 140, and the controller 150 may be implemented as a driver integrated circuit DIC of FIG. 1, separate from the display panel DP, and the driver integrated circuit DIC may be connected to the lines disposed in the non-display area NDA. In other embodiments, the gate driver 120 may be implemented as one integrated circuit separate from the display panel DP, together with the data driver 130, the voltage generator 140, and the controller 150.

In embodiments, the display area DA may have various shapes. The display area DA may have a closed loop shape including sides of a straight line and/or a curved line. For example, the display area DA may have shapes of a polygon, a circle, a semicircle, an ellipse, and the like within the spirit and the scope of the disclosure.

In embodiments, the display panel DP may have a flat display surface. In other embodiments, the display panel DP may have a display surface that is at least partially round. In embodiments, the display panel DP may be bendable, foldable, or rollable. In this case, the display panel DP and/or a substrate of the display panel DP may include materials having a flexible property.

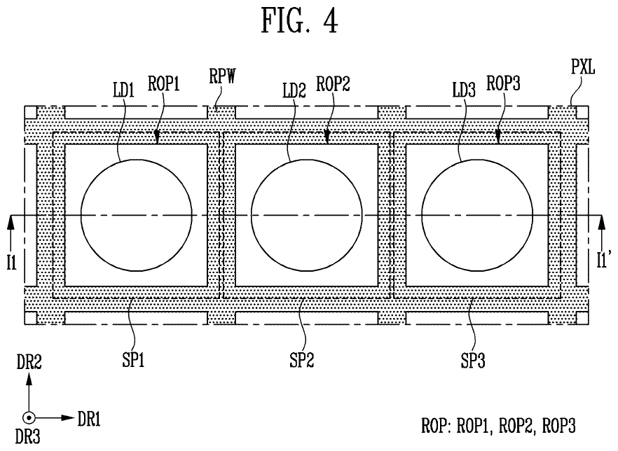

FIG. 4 is a schematic plan view illustrating a pixel according to an embodiment of the disclosure.

Referring to FIG. 4, the pixel PXL may include the first to third sub-pixels SP1, SP2, and SP3.

The first sub-pixel SP1 may include a first light emitting element LD1. The second sub-pixel SP2 may include a second light emitting element LD2. The third sub-pixel SP3 may include a third light emitting element LD3. The first to third light emitting elements LD1, LD2, and LD3 may be provided as the light emitting element LD described with reference to FIG. 2.

In FIG. 4, the first to third light emitting elements LD1, LD2, and LD3 of a cylindrical shape that is observed as a circle in a plan view are shown. However, a shape of the first to third light emitting elements LD1, LD2, and LD3 is not limited thereto. The first to third light emitting elements LD1, LD2, and LD3 may have various shapes according to an embodiment. For example, in case that the first to third light emitting elements LD1, LD2, and LD3 have a rectangular parallelepiped shape, a quadrangular shape may be observed in a plan view.

The pixel PXL may include a reflective partition wall (or reflective wall) RPW. The reflective partition wall RPW may define a reflective opening ROP. The reflective opening ROP may include first to third reflective openings ROP1, ROP2, and ROP3. The first reflective opening ROP1 may overlap the first light emitting element LD1 in a plan view. The second reflective opening ROP2 may overlap the second light emitting element LD2 in a plan view. The third reflective opening ROP3 may overlap the third light emitting element LD3 in a plan view.

In a plan view, the first reflective opening ROP1 may have a closed curve shape surrounding the first light emitting element LD1. For example, as shown in FIG. 4, the first reflective opening ROP1 may have a quadrangular shape in a plan view. Similarly, in a plan view, the second reflective opening ROP2 may have a closed curve shape surrounding the second light emitting element LD2, and the third reflective opening ROP3 may have a closed curve shape surrounding the third light emitting element LD3. However, a shape of the first to third reflective openings ROP1, ROP2, and ROP3 is not limited thereto.

The reflective partition wall RPW may be provided between adjacent light emitting elements. Accordingly, the reflective partition wall RPW may serve to prevent light mixing between the adjacent sub-pixels.

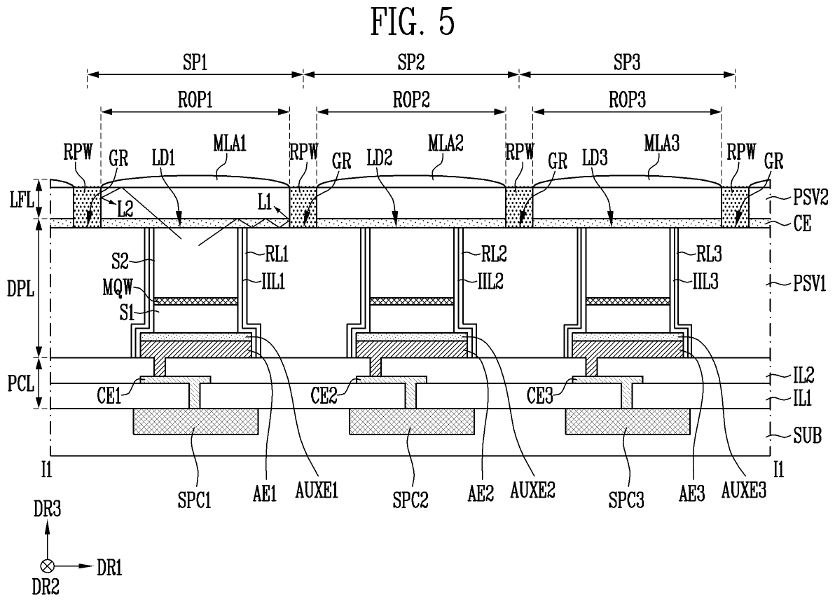

FIG. 5 is a schematic cross-sectional view illustrating a first embodiment of the pixel of FIG. 4.

Referring to FIGS. 4 and 5, the pixel PXL may include a substrate SUB, a pixel circuit layer PCL, a display element layer DPL, and a light function layer LFL.

In an embodiment, the substrate SUB may be a silicon substrate. The substrate SUB may be prepared in a semiconductor process using a silicon wafer. The substrate SUB may include first to third sub-pixel circuits SPC1, SPC2, and SPC3. The first sub-pixel circuit SPC1 may be provided as the sub-pixel circuit SPC (refer to FIG. 2) of the first sub-pixel SP1. The second sub-pixel circuit SPC2 may be provided as the sub-pixel circuit SPC (refer to FIG. 2) of the second sub-pixel SP2. The third sub-pixel circuit SPC3 may be provided as the sub-pixel circuit SPC (refer to FIG. 2) of the third sub-pixel SP3.

The pixel circuit layer PCL may be disposed on the substrate SUB. The pixel circuit layer PCL may include insulating layers and conductive layers disposed between the insulating layers. In an embodiment, the pixel circuit layer PCL may include a first insulating layer IL1, a second insulating layer IL2 disposed on the first insulating layer IL1, and first to third connection electrodes CE1, CE2, and CE3 disposed between the first insulating layer IL1 and the second insulating layer IL2.

The first and second insulating layers IL1 and IL2 may include an insulating material. In an embodiment, the first and second insulating layers IL1 and IL2 may include an inorganic insulating material. For example, the first and second insulating layers IL1 and IL2 may include an inorganic insulating material such as silicon oxide, silicon nitride, silicon oxynitride, aluminum oxide, or hafnium oxide.

The first to third connection electrodes CE1, CE2, and CE3 may include a conductive material. For example, the first to third connection electrodes CE1, CE2, and CE3 may include at least one material among copper (Cu), molybdenum (Mo), tungsten (W), aluminum (Al), titanium (Ti), and silver (Ag).

The first connection electrode CE1 may be connected to the first sub-pixel circuit SPC1 through a through hole passing through the first insulating layer IL1. The second connection electrode CE2 may be connected to the second sub-pixel circuit SPC2 through a through hole passing through the first insulating layer IL1. The third connection electrode CE3 may be connected to the third sub-pixel circuit SPC3 through a through hole passing through the first insulating layer IL1.

The pixel circuit layer PCL may further include various components such as a line and an electrode configuring the sub-pixel. In this case, as the number of layers required for forming the line, the electrode, and the like configuring the sub-pixel increases, the number of insulating layers and conductive layers included in the pixel circuit layer PCL may increase.

The display element layer DPL may be disposed on the pixel circuit layer PCL. The display element layer DPL may include first to third pixel electrodes AE1, AE2, and AE3, first to third auxiliary electrodes AUXE1, AUXE2, and AUXE3, the first to third light emitting elements LD1, LD2, and LD3, first to third element insulating layers IIL1, IIL2, and IIL3, first to third reflective layers RL1, RL2, and RL3, and the common electrode CE.

The first to third pixel electrodes AE1, AE2, and AE3 may be disposed on the second insulating layer IL2. The first to third pixel electrodes AE1, AE2, and AE3 may be spaced apart from each other. The first pixel electrode AE1 may be provided as the pixel electrode AE (refer to FIG. 2) of the first sub-pixel SP1, the second pixel electrode AE2 may be provided as the pixel electrode AE (refer to FIG. 2) of the second sub-pixel SP2, and the third pixel electrode AE3 may be provided as the pixel electrode AE (refer to FIG. 2) of the third sub-pixel SP3.

The first to third pixel electrodes AE1, AE2, and AE3 may include a conductive material. For example, the first to third pixel electrodes AE1, AE2, and AE3 may include at least one of various conductive materials such as aluminum (Al), silver (Ag), indium tin oxide (ITO), indium zinc oxide (IZO), zinc oxide (ZnO), indium gallium zinc oxide (IGZO), and indium tin zinc oxide (ITZO).

A first auxiliary electrode AUXE1 may be disposed on the first pixel electrode AE1. A second auxiliary electrode AUXE2 may be disposed on the second pixel electrode AE2. A third auxiliary electrode AUXE3 may be disposed on the third pixel electrode AE3. In an embodiment, the first to third auxiliary electrodes AUXE1, AUXE2, and AUXE3 may be formed of a conductive material having a selectable reflectance. For example, the first to third pixel electrodes AE1, AE2, and AE3 may include a metal such as silver (Ag), magnesium (Mg), aluminum (Al), platinum (Pt), palladium (Pd), gold (Au), nickel (Ni), neodymium (Nd), iridium (Ir), chromium (Cr), titanium (Ti), and/or an alloy thereof. In an embodiment, the first to third auxiliary electrodes AUXE1, AUXE2, and AUXE3 may include at least one of various transparent conductive materials such as indium tin oxide (ITO), indium zinc oxide (IZO), zinc oxide (ZnO), indium gallium zinc oxide (IGZO), and indium tin zinc oxide (ITZO).

According to embodiments, the first to third auxiliary electrodes AUXE1, AUXE2, and AUXE3 may be omitted.

The first light emitting element LD1 may be disposed on the first pixel electrode AE1. According to embodiments, the first auxiliary electrode AUXE1 may be disposed between the first light emitting element LD1 and the first pixel electrode AE1.

The first light emitting element LD1 may include a first semiconductor layer S1, an active layer MQW, and a second semiconductor layer S2 sequentially stacked along a third direction DR3.

The first semiconductor layer S1 may be connected to the first pixel electrode AE1. The first semiconductor layer S1 may include a semiconductor material having a first polarity. In an embodiment, the first semiconductor layer S1 may include a p-type semiconductor layer, and in this case, the first semiconductor layer S1 may provide a hole to the active layer MQW. For example, the first semiconductor layer S1 may include at least one semiconductor material among gallium nitride (GaN), aluminum gallium nitride (AlGaN), indium gallium nitride (InGaN), aluminum nitride (AlN), and indium nitride (InN), and may be a p-type semiconductor layer doped with a p-type dopant such as magnesium (Mg), zinc (Zn), calcium (Ca), strontium (Sr), and barium (Ba).

The second semiconductor layer S2 may be connected to the common electrode CE. The second semiconductor layer S2 may include a semiconductor material having a second polarity different from the first polarity. In an embodiment, the second semiconductor layer S2 may include an n-type semiconductor layer, and in this case, the second semiconductor layer S2 may provide an electron to the active layer MQW. For example, the second semiconductor layer S2 may include at least one semiconductor material among gallium nitride (GaN), aluminum gallium nitride (AlGaN), indium gallium nitride (InGaN), aluminum nitride (AlN), and indium nitride (InN), and may be an n-type semiconductor layer doped with an n-type dopant such as silicon (Si), germanium (Ge), or tin (Sn).

The active layer MQW may be disposed between the first semiconductor layer S1 and the second semiconductor layer S2. The active layer MQW may provide an area where the electron and the hole recombine. As the electron and the hole recombine in the active layer MQW, the electron and the hole may transit to a lower energy level, and light having a wavelength corresponding thereto may be generated. The active layer MQW may be formed in a single or multiple quantum well structure. In case that the active layer MQW is formed as in the multiple quantum well structure, a unit including a barrier layer, a strain reinforcing layer, and a well layer may be repeatedly stacked to form the active layer MQW. However, the active layer MQW is not limited thereto.

The second and third light emitting elements LD2 and LD3 may be configured similarly to the first light emitting element LD1. Therefore, an overlapping description may be omitted.

The first reflective layer RL1 may cover a side surface of the first light emitting element LD1. The first element insulating layer IIL1 may be disposed between the first reflective layer RL1 and the first light emitting element LD1. The second reflective layer RL2 may cover a side surface of the second light emitting element LD2. The second element insulating layer IIL2 may be disposed between the second reflective layer RL2 and the second light emitting element LD2. The third reflective layer RL3 may cover a side surface of the third light emitting element LD3. The third element insulating layer IIL3 may be disposed between the third reflective layer RL3 and the third light emitting element LD3.

The first to third reflective layers RL1, RL2, and RL3 may be formed of a material having a selectable reflectance. For example, the first to third reflective layers RL1, RL2, and RL3 may include a metal such as silver (Ag), magnesium (Mg), aluminum (Al), platinum (Pt), palladium (Pd), gold (Au), nickel (Ni), neodymium (Nd), iridium (Ir), chromium (Cr), titanium (Ti), and/or an alloy thereof. In this case, light emitted from the first to third light emitting elements LD1, LD2, and LD3 may be efficiently output toward the light functional layer LFL.

The first to third element insulating layers IIL1, IIL2, and IIL3 may include an inorganic insulating material. For example, the first to third element insulating layers IIL1, IIL2, and IIL3 may include silicon nitride, silicon oxide, silicon oxynitride, or the like within the spirit and the scope of the disclosure.

In an embodiment, the first reflective layer RL1 may further cover a side surface of the first pixel electrode AE1 and a side surface of the first auxiliary electrode AUXE1. In this case, the first element insulating layer IIL1 may be disposed between the first reflective layer RL1 and the first pixel electrode AE1, and between the first reflective layer RL1 and the first auxiliary electrode AUXE1.

Similarly, the second reflective layer RL2 may further cover a side surface of the second pixel electrode AE2 and a side surface of the second auxiliary electrode AUXE2. The second element insulating layer IIL2 may be disposed between the second reflective layer RL2 and the second pixel electrode AE2, and between the second reflective layer RL2 and the second auxiliary electrode AUXE2. The third reflective layer RL3 may further cover a side surface of the third pixel electrode AE3 and a side surface of the third auxiliary electrode AUXE3. The third element insulating layer IIL3 may be disposed between the third reflective layer RL3 and the third pixel electrode AE3, and between the third reflective layer RL3 and the third auxiliary electrode AUXE3.

A first passivation layer PSV1 may be disposed between the pixel circuit layer PCL and the common electrode CE. The first passivation layer PSV1 may include an inorganic insulating layer including an inorganic material and/or an organic insulating layer including an organic material. The inorganic insulating layer may include, for example, at least one of a metal oxide such as silicon nitride, silicon oxide, silicon oxynitride, or aluminum oxide. The organic insulating layer may include, for example, an acrylic resin, an epoxy resin, a phenol resin, a polyamide resin, a polyimide resin, an unsaturated polyester resin, a poly-phenylene ether resin, and benzocyclobutene resin.

The common electrode CE may be disposed on the first passivation layer PSV1 to face the first to third pixel electrodes AE1, AE2, and AE3. The common electrode CE may be connected to the second semiconductor layer S2 of the first to third light emitting elements LD1, LD2, and LD3.

The common electrode CE may be configured to be substantially transparent or translucent so as to satisfy a selectable light transmittance. For example, the common electrode CE may include at least one of various transparent conductive materials such as indium tin oxide (ITO), indium zinc oxide (IZO), zinc oxide (ZnO), indium gallium zinc oxide (IGZO), and indium tin zinc oxide (ITZO).

The light functional layer LFL may be disposed on the display element layer DPL. The light functional layer LFL may include a second passivation layer PSV2, the reflective partition wall RPW, and first to third light extraction structures (or first to third light extraction parts) MLA1, MLA2, and MLA3.

The second passivation layer PSV2 may be disposed on the common electrode CE. The second passivation layer PSV2 may include a material substantially equal or similar to the first passivation layer PSV1.

The reflective partition wall RPW may be disposed to fill a groove GR passing through the second passivation layer PSV2 and the common electrode CE in a direction opposite to the third direction DR3. In this case, the reflective partition wall RPW may directly contact an upper surface of the first passivation layer PSV1.

The reflective partition wall RPW may serve to prevent light mixing between adjacent sub-pixels. For example, first light L1 emitted from the first light emitting element LD1 may be totally reflected at interfaces between the common electrode CE and layers (for example, PSV1 and PSV2) contacting the common electrode CE and may proceed in a direction facing the second sub-pixel SP2. The first light L1 may be reflected by the reflective partition wall RPW. Therefore, the first light L1 may be prevented from mixing with light emitted from the second light emitting element LD2. As another example, second light L2 emitted from the first light emitting element LD1 may be totally reflected at an interface between the second passivation layer PSV2 and a layer (for example, MLA1) contacting the second passivation layer PSV2 and may proceed in a direction facing another sub-pixel adjacent to the first sub-pixel SP1. The second light L2 may be reflected by the reflective partition wall RPW. Therefore, the second light L2 may be prevented from mixing with light emitted from another light emitting element adjacent to the first light emitting element LD1.

In an embodiment, the reflective partition wall RPW may directly contact the common electrode CE. In this case, the common electrode CE of the first sub-pixel SP1 and the common electrode CE of the second sub-pixel SP2 may be electrically connected through the reflective partition wall RPW between the first sub-pixel SP1 and the second sub-pixel SP2. Similarly, the common electrode CE of the second sub-pixel SP2 and the common electrode CE of the third sub-pixel SP3 may be electrically connected through the reflective partition wall RPW between the second sub-pixel SP2 and the third sub-pixel SP3.

In an embodiment, the reflective partition wall RPW may be spaced apart from the first to third pixel electrodes AE1, AE2, and AE3 and the first to third auxiliary electrodes AUXE1, AUXE2, and AUXE3. Accordingly, the first to third pixel electrodes AE1, AE2, and AE3 and the first to third auxiliary electrodes AUXE1, AUXE2, and AUXE3 may be prevented from being electrically connected to the common electrode CE through the reflective electrode RPW.

In an embodiment, the reflective partition wall RPW may include a material of which a light transmittance is about 5% or less, a light reflectance is about 60% or more, and a resistance is about 10Ω or less. For example, the reflective partition wall RPW may include copper (Cu).

The first light extraction structure MLA1 may be disposed on the second passivation layer PSV2. The first light extraction structure MLA1 may be disposed in the first reflective opening ROP1. For example, the first light extraction structure MLA1 may be surrounded by the first reflective opening ROP1 in a plan view. The first light extraction structure MLA1 may be configured to be convex in the third direction DR3. The first light extraction structure MLA1 may serve to improve light efficiency of the light emitted from the first light emitting element LD1.

The second and third light extraction structures MLA2 and MLA3 may be configured substantially the same as the first light extraction structure MLA1. For example, the second light extraction structure MLA2 may be surrounded by the second reflective opening ROP2 in a plan view. The third light extraction structure MLA3 may be surrounded by the third reflective opening ROP3 in a plan view.

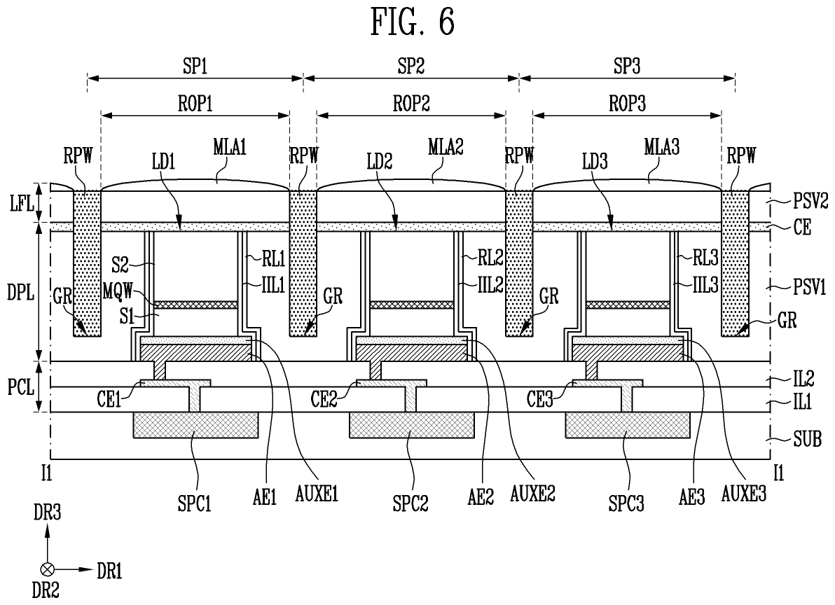

FIG. 6 is a schematic cross-sectional view illustrating a second embodiment of the pixel of FIG. 4.

Hereinafter, a difference compared to the first embodiment described with reference to FIG. 5 is described, and a part of which a description may be omitted may be replaced with the content described above.

Referring to FIGS. 4 and 6, the groove GR may further pass through the first passivation layer PSV1 adjacent to the common electrode CE. For example, a distance of the third direction DR3 from a lower surface of the groove GR to an upper surface of the pixel circuit layer PCL may be substantially the same as a distance of the third direction DR3 from an upper surface of the pixel circuit layer PCL to an upper surface of the first auxiliary electrode AUXE1. The reflective partition wall RPW may be configured to fill the groove GR. Accordingly, light mixing between adjacent sub-pixels may be more effectively prevented by the reflective partition wall RPW.

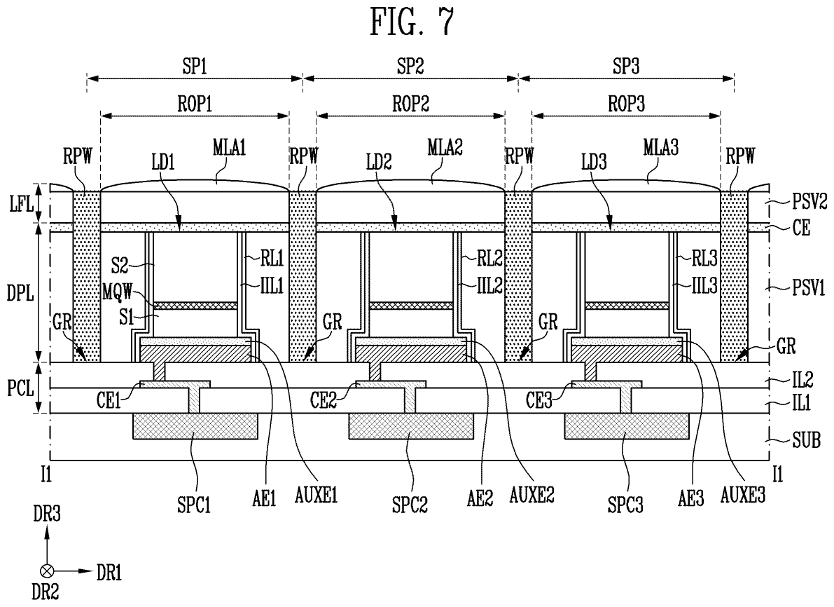

FIG. 7 is a schematic cross-sectional view illustrating a third embodiment of the pixel of FIG. 4.

Hereinafter, a difference compared to the first embodiment described with reference to FIG. 5 is described, and a part of which a description may be omitted may be replaced with the content described above.

Referring to FIGS. 4 and 7, the groove GR may further pass through the first passivation layer PSV1 to expose the upper surface of the pixel circuit layer PCL. The reflective partition wall RPW may be configured to fill the groove GR. Accordingly, light mixing between adjacent sub-pixels may be more effectively prevented by the reflective partition wall RPW.

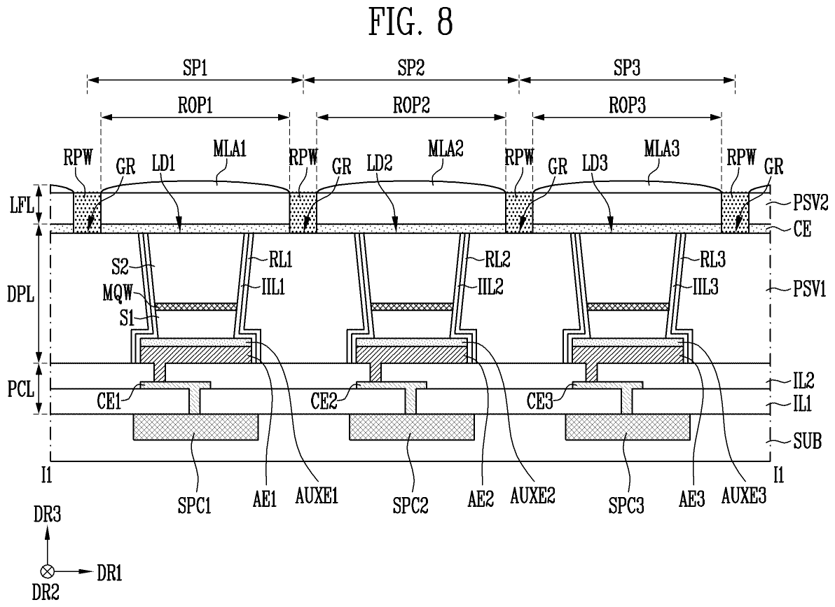

FIG. 8 is a schematic cross-sectional view illustrating a fourth embodiment of the pixel of FIG. 4.

Hereinafter, a difference compared to the first embodiment described with reference to FIG. 5 is described, and a part of which a description may be omitted may be replaced with the content described above.

Referring to FIGS. 4 and 8, in a cross-sectional view, the first to third light emitting elements LD1, LD2, and LD3 may have a reverse taper shape in which a width gradually increases along the third direction DR3. In this case, the first to third reflective layers RL1, RL2, and RL3 covering side surfaces of the first to third light emitting elements LD1, LD2, and LD3 may also have a reverse taper shape in a cross-sectional view. Accordingly, light emitted from the first to third light emitting elements LD1, LD2, and LD3 may be more efficiently output toward the light function layer LFL by light reflection by the first to third reflective layers RL1, RL2, and RL3.

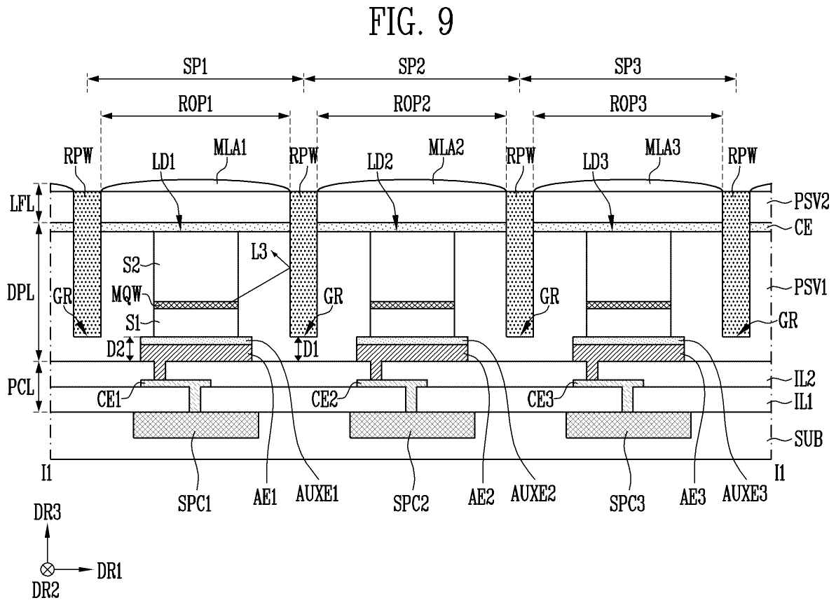

FIG. 9 is a schematic cross-sectional view illustrating a fifth embodiment of the pixel of FIG. 4.

Hereinafter, a difference compared to the first embodiment described with reference to FIG. 5 is described, and a part of which a description may be omitted may be replaced with the content described above.

Referring to FIGS. 4 and 9, the first to third element insulating layers IIL1, IIL2, and IIL3 and the first to third reflective layers RL1, RL2, and RL3 described with reference to FIG. 5 may be omitted. In this case, side surfaces of the first to third light emitting elements LD1, LD2, and LD3 may directly contact the first passivation layer PSV1.

In an embodiment, the groove GR may be configured to pass through the second passivation layer PSV2, the common electrode CE, and the first passivation layer PSV1 in a direction opposite to the third direction DR3.

In an embodiment, a first distance D1 of the third direction DR3 from the lower surface of the groove GR to the upper surface of the pixel circuit layer PCL may be less than a second distance D2 of the third direction DR3 from the upper surface of the pixel circuit layer PCL to the upper surface of the first auxiliary electrode AUXE1. In this case, third light L3 emitted from the first light emitting element LD1 toward the first passivation layer PSV1 may be reflected by the reflective partition wall RPW filling the groove GR. Therefore, light mixing between adjacent sub-pixels may be prevented. For example, the reflective partition wall RPW may further serve as the first to third reflective layers RL1, RL2, and RL3 described with reference to FIG. 5.

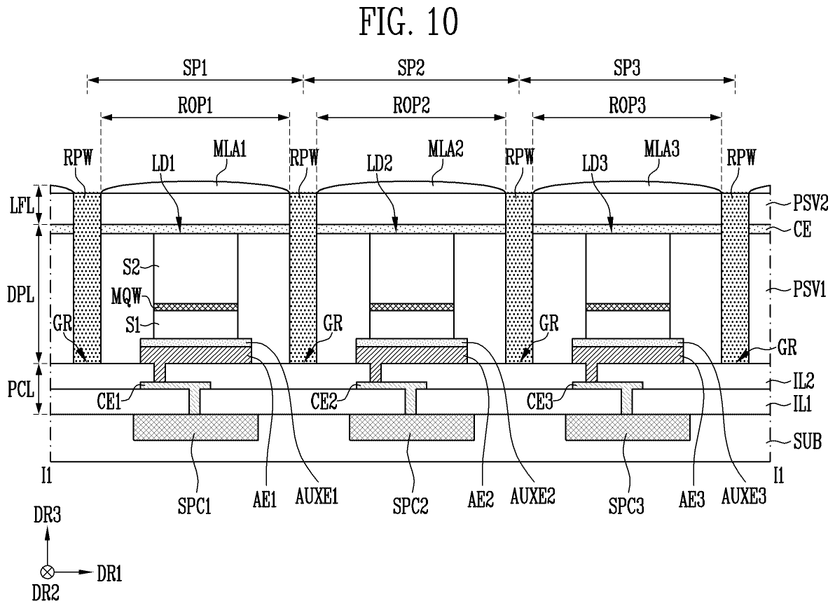

FIG. 10 is a schematic cross-sectional view illustrating a sixth embodiment of the pixel of FIG. 4.

Hereinafter, a difference compared to the fifth embodiment described with reference to FIG. 9 is described, and a part of which a description may be omitted may be replaced with the content described above.

Referring to FIGS. 4 and 10, the groove GR may expose the upper surface of the pixel circuit layer PCL. The reflective partition wall RPW may be configured to fill the groove GR. Accordingly, light mixing between adjacent sub-pixels may be more effectively prevented by the reflective partition wall RPW.

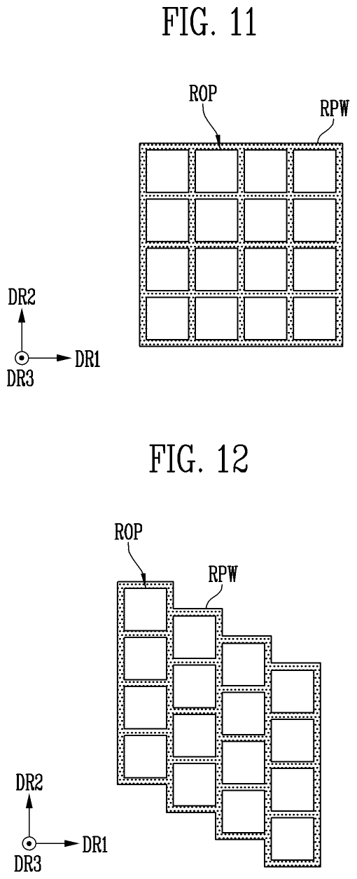

FIGS. 11 to 15 are schematic plan views illustrating a reflective partition wall according to embodiments of the disclosure.

Referring to FIGS. 11 to 15, the reflective partition wall RPW may have various shapes in a plan view to correspond to a disposition of the light emitting elements LD1, LD2, and LD3 in a plan view.

The reflective openings ROP defined in the reflective partition wall RPW may be disposed to correspond to the disposition of the light emitting elements LD1, LD2, and LD3 in a plan view. For example, in case that the light emitting elements LD1, LD2, and LD3 are disposed in a matrix form in a plan view, the reflective partition wall RPW may have a shape in a plan view as shown in FIG. 11. As another example, in case that the light emitting elements LD1, LD2, and LD3 are disposed in a shape other than a matrix form in a plan view, the reflective partition wall RPW may have various shapes as shown in FIGS. 12 to 15 corresponding to the disposition of the light emitting elements LD1, LD2, and LD3 in a plan view.

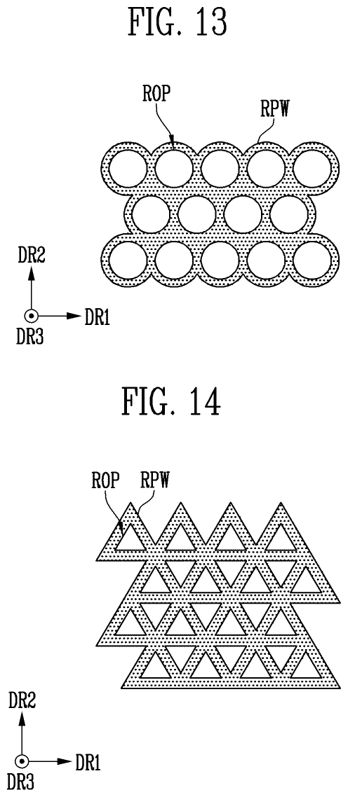

The reflective openings ROP defined in the reflective partition wall RPW may have various shapes in a plan view. For example, as shown in FIGS. 11 and 12, the reflective openings ROP may have a quadrangular shape in a plan view. As another example, as shown in FIG. 13, the reflective openings ROP may be circular in a plan view. As still another example, as shown in FIGS. 14 and 15, the reflective openings ROP may have a polygonal shape in a plan view.

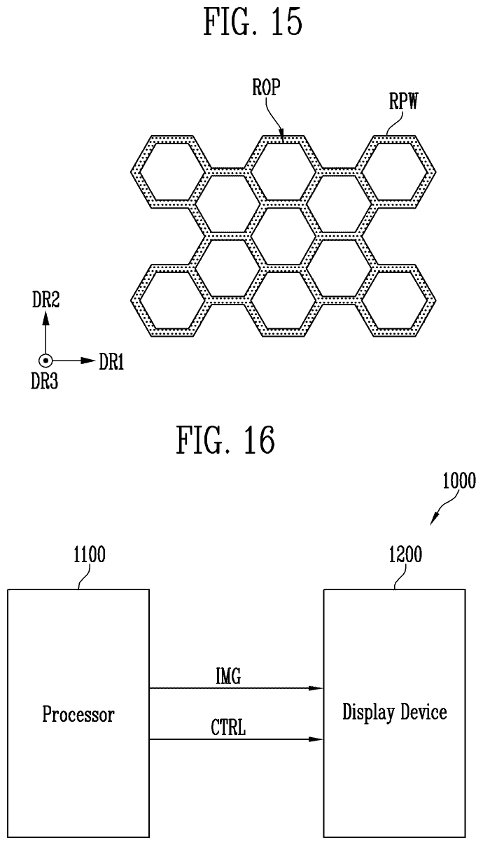

FIG. 16 is a block diagram illustrating a display system according to an embodiment.

Referring to FIG. 16, the display system 1000 may include a processor 1100 and a display device 1200.

The processor 1100 may perform various tasks and calculations. In embodiments, the processor 1100 may include an application processor, a graphics processor, a microprocessor, a central processing unit (CPU), and the like within the spirit and the scope of the disclosure. The processor 1100 may be connected to other components of the display system 1000 through a bus system to control the other components.

The processor 1100 may transmit image data IMG and a control signal CTRL to the display device 1200. The display device 1200 may display an image based on the image data IMG and the control signal CTRL. The display device 1200 may be configured similarly to the display device DD described with reference to FIG. 1. In this case, the image data IMG and the control signal CTRL may be provided as the input image data IMG and the control signal CTRL of FIG. 1, respectively.

The display system 1000 may include a computing system providing an image display function, such as a smart watch, a mobile phone, a smart phone, a portable computer, a tablet personal computer (PC), a watch phone, an automotive display, smart glasses, a portable multimedia player (PMP), a navigation device, and an ultra mobile personal computer (UMPC). The display system 1000 may include at least one of a head mounted display (HMD) device, a virtual reality (VR) device, a mixed reality (MR) device, and an augmented reality (AR) device.

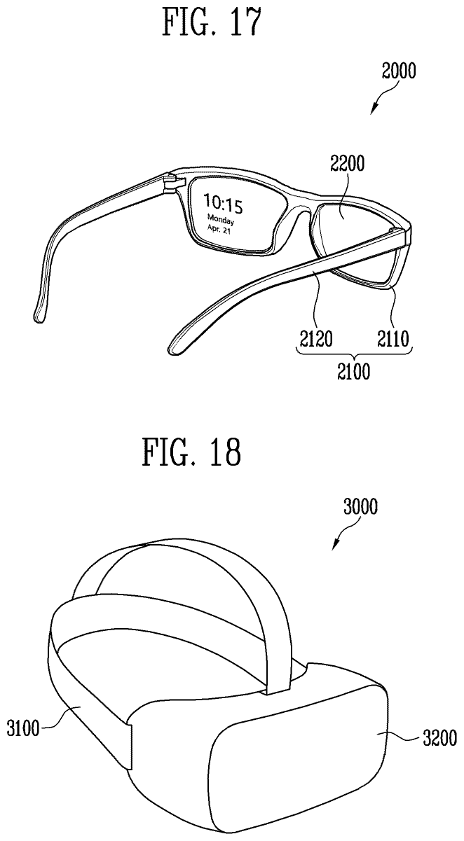

FIGS. 17 and 18 are schematic perspective views illustrating application examples of the display system of FIG. 16.

Referring to FIG. 17, the display system 1000 of FIG. 16 may be applied to smart glasses 2000. The smart glasses 2000 may be a wearable electronic device that may be worn on a user's head. For example, the smart glasses 2000 may be a wearable device for augmented reality.

The smart glasses 2000 may include a frame 2100 and a lens unit 2200. The frame 2100 may include a housing 2110 that supports the lens unit 2200 and a leg unit 2120 for the user to wear. The leg unit 2120 may be connected to the housing 2110 through a hinge and may be folded or unfolded relative to the housing 2110.

A battery, a touch pad, a microphone, a camera, and the like may be built in the frame 2100. A projector that outputs light, a processor that controls a light signal, and the like may be built in the frame 2100.

The lens unit 2200 may include an optical member that transmits or reflects light. For example, the lens unit 2200 may include glass, transparent synthetic resin, or the like within the spirit and the scope of the disclosure.

In order for user's eyes to recognize visual information, the lens unit 2200 may reflect an image by the light signal transmitted from the projector of the frame 2100 by a rear surface (for example, a surface of a direction facing the user's eyes) of the lens unit 2200. For example, the user may recognize visual information such as time and date displayed on the lens unit 2200. At this time, the projector and/or the lens unit 2200 may be a type of display device. The display device 1200 may be applied to the projector and/or the lens unit 2200.

Referring to FIG. 18, the display system 1000 of FIG. 16 may be applied to a head mounted display device 3000.

The head mounted display device 3000 may be a wearable electronic device that may be worn on a user's head. For example, the head mounted display device 3000 may be a wearable device for virtual reality or mixed reality.

The head mounted display device 3000 may include a head mount band 3100 and a display device receiving case 3200. The head mount band 3100 may be connected to the display device receiving case 3200. The head mount band 3100 may include a horizontal band and/or a vertical band for fixing the head mounted display device 3000 to a user's head. The horizontal band may be configured to surround a side portion of the user's head, and the vertical band may be configured to surround an upper portion of the user's head. However, embodiments are not limited thereto. For example, the head mount band 3100 may be implemented in a form of a glasses frame, a helmet, or the like within the spirit and the scope of the disclosure.

The display device receiving case 3200 may receive the display system 1000 and/or the display device 1200.

An electronic device may be at least one of an organic light-emitting display apparatus, an inorganic light-emitting display apparatus, a quantum dot light-emitting display apparatus, display screens of portable electronic apparatus, such as mobile phones, smartphones, tablet personal computers (PCs), mobile communication terminals, electronic notebooks, electronic books, portable multimedia players (PMPs), navigation devices, and ultra mobile PCs (UMPCs), display screens of televisions, notebooks, monitors, advertisement panels, Internet of things (IoT) devices, a portable communication device a smartphone, a computer device, a portable multimedia device, a portable medical device, a camera, a wearable device, and a home appliance.

Although described with reference to the above embodiments, it will be understood that those skilled in the art can variously modify and change the disclosure without departing from the spirit and scope of the disclosure and as described in the claims below.

What is claimed is:

1. A display device comprising:
a pixel electrode disposed on a pixel circuit layer;
a common electrode facing the pixel electrode;
a light emitting element disposed between the pixel electrode and the common electrode, and including:
a first semiconductor layer connected to the pixel electrode,
a second semiconductor layer connected to the common electrode, and
an active layer disposed between the first semiconductor layer and the second semiconductor layer;
a reflective layer covering a side surface of the light emitting element;
an element insulating layer disposed between the reflective layer and the light emitting element;
a first passivation layer disposed between the pixel circuit layer and the common electrode;
a second passivation layer disposed on the common electrode; and
a reflective wall defining a closed curve shape of a reflective opening surrounding the light emitting element in a plan view,
wherein the reflective wall fills a groove passing through the second passivation layer and the common electrode in a direction facing the pixel circuit layer.

2. The display device of claim 1, wherein the reflective wall directly contacts the common electrode.

3. The display device of claim 1, wherein the groove further passes through the first passivation layer adjacent to the common electrode.

4. The display device of claim 3, wherein the groove exposes an upper surface of the pixel circuit layer.

5. The display device of claim 1, further comprising:
a light extraction part disposed on the second passivation layer, surrounded by the reflective opening in a plan view, and convex in a direction opposite to the direction facing the pixel circuit layer.

6. The display device of claim 1, wherein the reflective wall is spaced apart from the pixel electrode.

7. The display device of claim 1, wherein
the reflective layer covers a side surface of the pixel electrode, and
the element insulating layer is disposed between the pixel electrode and the reflective layer.

8. The display device of claim 1, further comprising:
an auxiliary electrode disposed between the pixel electrode and the first semiconductor layer.

9. The display device of claim 8, wherein the reflective wall is spaced apart from the auxiliary electrode.

10. The display device of claim 1, wherein
the reflective wall includes a material of which a light transmittance is about 5% or less,
a light reflectance is about 60% or more, and
a resistance is about 10Ω or less.

11. The display device of claim 10, wherein the reflective wall includes copper.

12. The display device of claim 1, wherein the light emitting element has a reverse taper shape in which a width gradually increases along a direction away from the pixel circuit layer, in a cross-sectional view.

13. A display device comprising:
a pixel electrode disposed on a pixel circuit layer;
a common electrode facing the pixel electrode;
a light emitting element disposed between the pixel electrode and the common electrode, and including:
a first semiconductor layer connected to the pixel electrode,
a second semiconductor layer connected to the common electrode, and
an active layer disposed between the first semiconductor layer and the second semiconductor layer;
a first passivation layer disposed between the pixel circuit layer and the common electrode;
a second passivation layer disposed on the common electrode; and
a reflective wall defining a closed curve shape of a reflective opening surrounding the light emitting element in a plan view,
wherein the reflective wall fills a groove passing through the second passivation layer, the common electrode, and the first passivation layer in a direction facing the pixel circuit layer.

14. The display device of claim 13, wherein the first passivation layer directly contacts a side surface of the light emitting element.

15. The display device of claim 13, wherein the groove exposes an upper surface of the pixel circuit layer.

16. The display device of claim 13, wherein the reflective wall directly contacts the common electrode.

17. The display device of claim 13, further comprising:
a light extraction part disposed on the second passivation layer, surrounded by the reflective opening in a plan view, and convex in a direction opposite to the direction facing the pixel circuit layer.

18. The display device of claim 13, wherein the reflective wall is spaced apart from the pixel electrode.

19. The display device of claim 13, further comprising:
an auxiliary electrode disposed between the pixel electrode and the first semiconductor layer, wherein
the reflective wall is spaced apart from the auxiliary electrode.

20. An electronic device comprising:
a processor that provides input image data; and
a display device that displays an image based on the input image data,
wherein the display device comprises:
a pixel electrode disposed on a pixel circuit layer;
a common electrode facing the pixel electrode;
a light emitting element disposed between the pixel electrode and the common electrode, and including a first semiconductor layer connected to the pixel electrode, a second semiconductor layer connected to the common electrode, and an active layer disposed between the first semiconductor layer and the second semiconductor layer;
a reflective layer covering a side surface of the light emitting element;
an element insulating layer disposed between the reflective layer and the light emitting element;
a first passivation layer disposed between the pixel circuit layer and the common electrode;
a second passivation layer disposed on the common electrode; and
a reflective wall defining a closed curve shape of a reflective opening surrounding the light emitting element in a plan view,
the reflective wall fills a groove passing through the second passivation layer and the common electrode in a direction facing the pixel circuit layer.
